(19) United States
(12) Patent Application Publication
(10) Pub. No.: US 2015/0355302 A1
(43) Pub. Date: Dec. 10, 2015

(54) SIMULTANEOUS MR IMAGING METHOD AND APPARATUS FOR SIMULTANEOUS MULTI-NUCLEAR MR IMAGING

(71) Applicant: SIEMENS AKTIENGESELLSCHAFT, MÜNCHEN (DE)

(72) Inventors: HUBERTUS FISCHER, BAMBERG (DE); ROBERT KRIEG, NÜRNBERG (DE); JAN RUFF, MÜNCHEN (DE)

(21) Appl. No.: 14/721,034

(22) Filed: May 26, 2015

(30) Foreign Application Priority Data
Jun. 4, 2014 (DE) 102014210599.4

(51) Int. Cl. G01R 33/561; G01R 33/385; G01R 33/30

(52) U.S. Cl. CPC G01R 33/5612; G01R 33/5615; G01R 33/307; G01R 33/385

(57) ABSTRACT

A simultaneous MR imaging method is described in which different types of atom are simultaneously excited and read out. First a multi-resonant RF excitation pulse is transmitted including a plurality of sub-signals assigned to different types of atom and having different frequency ranges. Simultaneously or in a synchronized manner, a gradient scheme common to the different types of atom is transmitted with which an unambiguous spatial assignment of received signals can be performed. In the subsequent readout process, an echo signal is received including different individual echoes of different types of atom. The received echo signal is separated into individual signals. Finally, image data is reconstructed from raw data obtained from the separated individual signals. Also described is an apparatus with which the above described method can be carried out.

### CROSS-REFERENCE TO RELATED APPLICATION

This application claims priority to DE 102014210599.4 having a filing date of Jun. 4, 2014, the entire contents of which are hereby incorporated by reference.

### FIELD OF TECHNOLOGY

The following relates to a simultaneous MR imaging method and to an apparatus for simultaneous imaging. The following also relates to a magnetic resonance system.

### BACKGROUND

In a magnetic resonance system, also known as a magnetic resonance tomography system, the body being scanned is exposed to a relatively high main magnetic field of e.g. 1, 3, 5 or 7 teslas using a main field magnet system. In addition, a gradient system is used to apply a magnetic field gradient. Radiofrequency excitation signals (RF signals) are then emitted via a radiofrequency transmitting system using suitable antenna devices, which is designed to cause the nuclear spins of particular atoms resonantly excited by this radiofrequency field to be tilted by a defined flip angle relative to the magnetic lines of force of the main magnetic field. As the nuclear spins relax, radiofrequency signals, so-called magnetic resonance signals, are emitted which are received using suitable receive antennas and then further processed. The desired image data can then be reconstructed from the thus acquired raw data. The image data represents sectional images of the density or relaxation of the atomic nuclei having magnetically polarizable nuclear spins.

For a particular scan, a particular pulse sequence must therefore be emitted which consists of a string of radiofrequency pulses, in particular excitation pulses and refocusing pulses as well as gradient pulses to be emitted in an appropriately coordinated manner in different spatial directions. Suitably timed readout windows must be set which predefine the time segments in which the induced magnetic resonance signals are acquired. Critical for imaging here is the timing within the sequence, i.e. what pulses follow one another at what time intervals. A large number of the control parameters are generally defined in a so-called scan protocol which is created in advance and called up e.g. from a memory for a particular scan and can in some cases be changed locally by the operator who can specify additional control parameters such as e.g. a particular inter-slice separation of a stack of slices to be scanned, a slice thickness, etc. A pulse sequence, which is also termed a scanning sequence, is then calculated on the basis of all these control parameters. Usually only one type of atom, namely hydrogen, is excited. The pulse sequence or scan protocol used is therefore usually optimized for hydrogen.

In order to obtain further information about the physiological and metabolic state of the patient, it may be advisable to also excite other types of atom or other specific types of isotope in addition to imaging based on hydrogen atoms.

For example, additional imaging can be performed by exciting sodium ions Na²³. Sodium ions are important for cellular homeostasis and cell survival. Healthy tissue has an extracellular sodium concentration of 145 mM which exceeds the intracellular concentration by approximately a factor of 10. An MR scan of Na²³ ions enables volume- and relaxation-weighted signals of these compartments to be measured. In this context, magnetic resonance tomography using Na²³ ions is a diagnostic aid for detecting pathological processes which produce a change in the Na²³ ion gradient. NA²³ and H¹ images are usually taken in separate passes and using different pulse sequences geared to the individual types of atom. This is because the requirements imposed by Na²³ MRT imaging are significantly different from those of hydrogen-based MRT imaging. The challenges of Na²³ MRT imaging result, one the one hand, from a poorer SNR (signal-to-noise ratio). Longer scan times are therefore necessary in order to achieve sufficient image quality. Also with Na²³ MRT imaging the signal strength of the received signals is much lower. The total concentration of Na²³ is only about 50 mM in brain tissue and about 30 mM in muscle. The MR sensitivity of Na²³ is a factor of 10 less than the sensitivity of hydrogen. This results in a signal strength of the in vivo signal of Na²³ MR imaging that is about 20000 times lower than the signal in H¹ MR imaging. This sensitivity difference can be partly compensated by shorter repetition times (TR), as the longitudinal relaxation times T₁ are much shorter compared to H¹ imaging. However, the overall sensitivity is more than a factor of 2000 lower.

In addition, Na²³ has a lower-value coupling constant γ than H¹. For this reason, in the case of Na²³ imaging, a gradient field having a higher field strength must be applied for encoding by means of the gradient pulses than for imaging using hydrogen atoms. Lastly, Na²³ atoms have shorter transverse echo times in vivo than H¹ atoms, which requires shorter echo times and therefore faster sequences.

However, serial MR imaging using different types of atom is more time-consuming. In addition, with serial scanning the problem arises that the patient's position may have changed between the scans. Moreover, during serial acquisition, effects due to respiration, heartbeat and similar changes can have different effects on the consecutively acquired images because of the different acquisition times. This makes it more difficult to compare the serial scans performed using different types of atom.

### SUMMARY

An aspect relates to developing a faster, less error-prone and more convenient MR imaging method using resonance signals of atoms of different types.

An underlying idea of embodiments of the invention can be seen in that different types of atom can be simultaneously excited and read out using the inventive MR imaging method. First a multi-resonant RF excitation pulse is transmitted which comprises a plurality of sub-signals assigned to different types of atom and having different frequency ranges. Simultaneously or in a synchronized manner, a gradient scheme common to the different types of atom is transmitted, enabling an unambiguous spatial assignment of received signals to be performed. In the subsequent readout process, an echo signal is received which comprises different individual echoes of different atom types. The received echo signal is separated into individual signals. As the individual signals comprise different frequencies, the individual signals can be easily filtered out. Finally the image data is reconstructed from the raw data obtained from the separated individual signals.

The apparatus according to embodiments of the invention has a transmit unit comprising a multi-resonant transmit antenna which is designed to transmit a multi-resonant RF excitation pulse comprising a plurality of sub-signals assigned to a plurality of different types of atom, and to transmit a gradient scheme common to the different types of atom. The multi-resonant transmit antenna can comprise, for example, a plurality of transmit antennas tuned to different frequencies. Alternatively, the transmit antenna can also be resonant to a plurality of frequencies as a single antenna. The apparatus according to embodiments of the invention also has a receive unit comprising a multi-resonant receive antenna which is designed to receive an echo signal comprising different individual echoes of different types of atom. The apparatus according to the embodiments of invention also has a separation unit which is designed to separate the echo signal into individual signals, and a reconstruction unit which is designed to reconstruct image data on the basis of raw data assigned to the separated individual signals.

The magnetic resonance system according to embodiments of the invention incorporates the apparatus according to embodiments of the invention. The individual units of the apparatus according to embodiments of the invention can also be parts of different units such as a scan control unit, a receive unit or an evaluation unit.

Most of the previously mentioned components of the apparatus according to embodiments of the invention, in particular the separation unit and the reconstruction unit, can be implemented wholly or partly in the form of software modules. This is advantageous in that, by installing software, existing hardware devices can also be upgraded to carry out the method according to embodiments of the invention. Embodiments of the invention therefore also comprises a computer program which can be directly loaded into a processor of a programmable control device of a magnetic resonance system and having program code means of executing all the steps of the method according to embodiments of the invention when the program is executed in the programmable control device. Said control device can also comprise distributed units such as, for example, a scan control unit, a reconstruction unit, an evaluation unit, etc. or also be part of the apparatus as claimed and control the units incorporated in the apparatus as claimed, so that the method according to embodiments of the invention can be carried out.

Other particularly advantageous embodiments and further developments of embodiments of the invention will emerge from the dependent claims and the following description, wherein the independent claims of one claim category can also be further developed analogously to the dependent claims of another claim category.

In a preferred embodiment of the method, a multi-resonant RF inversion pulse is transmitted which comprises a plurality of sub-signals assigned to different types of atom. The transmitting of an RF inversion pulse is used to refocus the spins excited by the RF excitation pulse. For example, the phase of the spins is rotated through 180°, i.e. inverted. This approach is used for transmitting spin echo sequences. Alternatively, for gradient echo sequences such as GRE, Flash, Fisp, TrueFisp etc., an inverted gradient pulse can also be transmitted which is likewise used for refocusing the spins of the atoms excited. Combinations of spin echo sequences and gradient echo sequences such as e.g. TSE, HASTE, TGSE, etc. can also be used.

In a particularly preferred variant of the method according to the invention, the echo signals of just two types of atom are scanned. The method can be particularly advantageously used for simultaneously exciting hydrogen and sodium atoms. This is advantageous if both high-resolution imaging and identification of pathological processes causing a change in the Na²³ gradient are to be carried out.

Alternatively, the atoms excited during the simultaneous imaging method can also comprise atom types such as F¹⁹, O¹⁷, P³¹, C¹⁴, Li⁷, Cl³⁵, Cl³⁷ or He in addition or alternatively to the atom types H¹, Na²³.

In one embodiment of the invention, the common gradient scheme can be optimized in respect of the resonance of hydrogen atoms. Because, due to the higher value of the coupling constant γ, the echo signals assigned to the hydrogen atoms produce a significantly better image resolution, so that the image generated using the atoms reproduces the most details and is accordingly also optimized for accuracy or minimum interference effects.

However, a reverse process can also be useful. As H¹ always has the most signal, a sub-optimum but adequate sequence can be designed for this nucleus, said sequence achieving the maximum signal from the lower-resonance nuclei (having a lower SNR).

The method according to embodiments of the invention can be used for slice-selective pulse sequences, wherein the RF excitation pulses and possibly the RF inversion pulses are emitted slice-selectively. The bandwidth of the RF pulses of the different types of atom is adjusted for the different frequency ranges, taking a common slice selection gradient into account, such that the slice thicknesses are identical.

To ensure that the slice thicknesses are identical during slice-selective excitation of the different atoms, the ratios of the bandwidths of the sub-signals of the multi-resonant RF excitation pulses are selected such that they correspond to the ratios of the gyromagnetic factors of the different types of atom.

If the method according to embodiments of the invention is used for a spin echo sequence, the ratios of the bandwidths of the sub-signals of the multi-resonant RF inversion pulses are also selected such that they correspond to the ratios of the values of the gyromagnetic factors of the different types of atom.

Alternatively to slice-selective excitation, the method according to embodiments of the invention can also be used for 3D sequences. For this type of sequences, a phase encoding scheme is also run in the z-direction instead of a slice-selective gradient. In this case it is unnecessary for slice thicknesses to be adjusted. Therefore, in this variant the bandwidths of the applied excitation pulses, i.e. inversion pulses, no longer have to correspond to the respective coupling constants γ of the individual types of atom. In this case, three-dimensional regions are “cut off” in order to cover the same FoV as for hydrogen. In other words, the third direction (slice direction) must be treated exactly like the 2D phase encoding direction in this case.

After readout of the echo signal or separation into individual signals, the separated individual signals are preferably converted into digital signals. The digital signals constitute raw data which can be further processed using digital circuits.

In a particularly practicable variant of the method according to the invention, separated image data is obtained from the separated individual signals of the different types of atom. Here the image data pixels lying outside the image region are discarded after image reconstruction, with the exception of the atom having the highest-value coupling constant, e.g. hydrogen. Graphically expressed, the image regions of the image data assigned to the other types of atom and lying outside the image region of the acquired image to the atom having the highest-value coupling constant are not taken into account. The different image sizes of the views assigned to the individual types of atom are due to the fact that the FoV is inversely proportional to the value of the atom-type-specific coupling constant γ.

Alternatively, during readout of the echo signals, k-space can also be sampled radially instead of line by line. In addition to radial sampling of k-space, spiral sampling or EPI-type sampling of k-space can be performed.

The method according to embodiments of the invention can also be varied such that the RF pulses for different types of atom are transmitted sequentially instead of simultaneously, but during the same common gradient pulse. This variant can be useful particularly when conventional magnetic resonance systems are to be upgraded to the new method.

### BRIEF DESCRIPTION

Some of the embodiments will be described in detail, with reference to the following figures, wherein like designations denote like members, wherein:

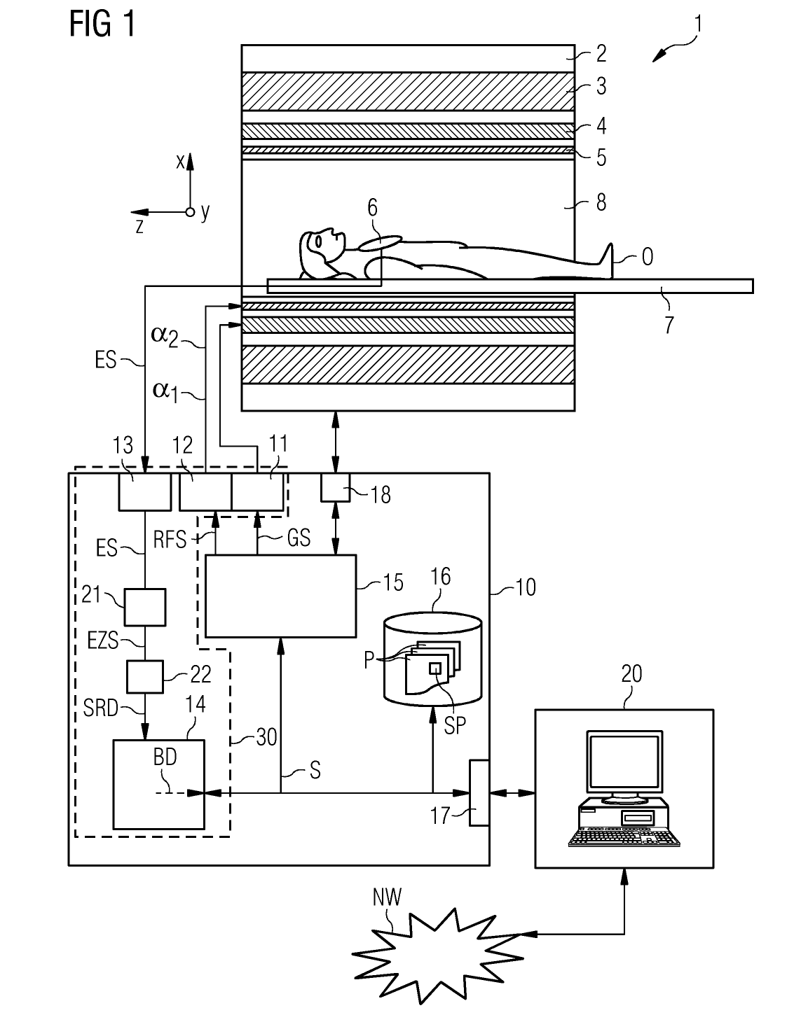

FIG. 1 schematically illustrates a magnetic resonance system according to an exemplary embodiment of the invention;

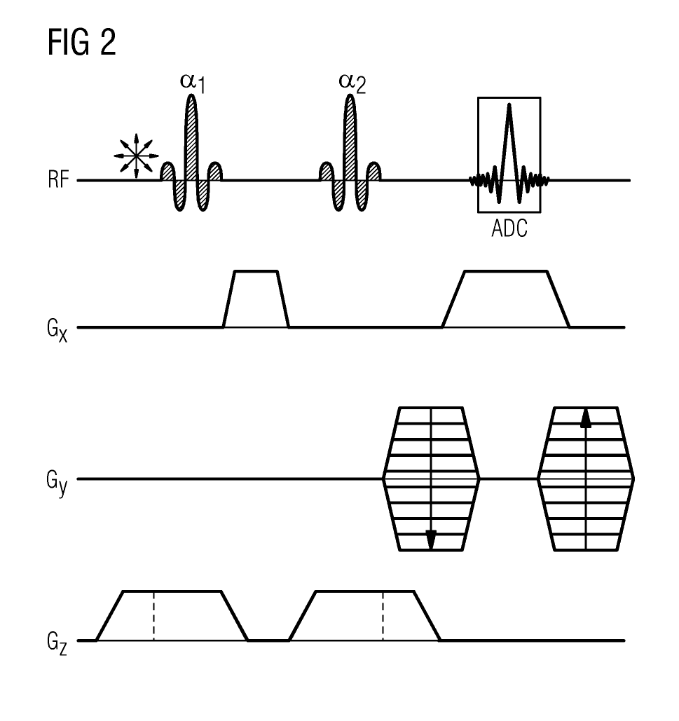

FIG. 2 schematically illustrates a pulse sequence which is used for a method according to an exemplary embodiment of the invention and

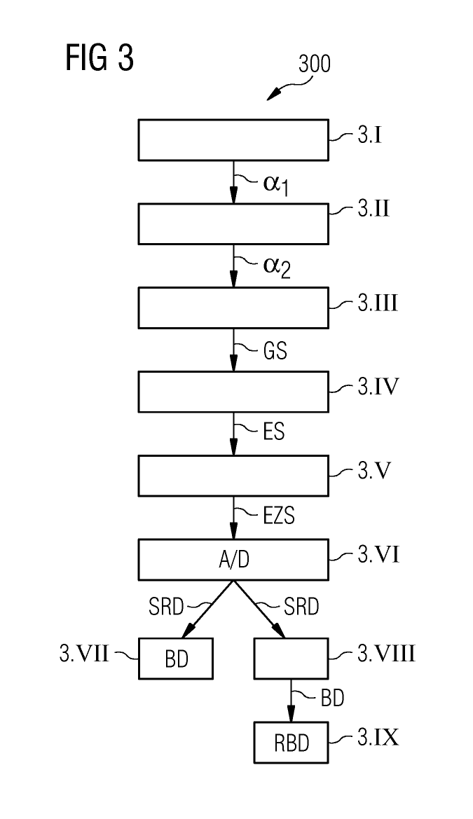

FIG. 3 shows a flow chart illustrating an embodiment of a method.

### DETAILED DESCRIPTION

FIG. 1 shows an extremely schematic representation of a magnetic resonance system 1. It comprises on the one hand the actual magnetic resonance scanner 2 incorporating a scanning chamber 8 or patient tunnel 8. A couch 7 can be moved into said patient tunnel 8 so that during a scan a patient O or examinee lying thereon can be supported in a particular position inside the magnetic resonance scanner 2 relative to the magnet system and radiofrequency system disposed therein, or can also be moved between different positions during a scan.

The basic components of the magnetic resonance scanner 2 are a main field magnet 3, a gradient system 4 having magnetic field gradient coils for generating magnetic field gradients in the x-, y- and z-directions, and an RF body coil 5. The magnetic field gradient coils in the x-, y- and z-direction can be controlled independently of one another so that, by means of a predefined combination, gradients can be applied in any logical spatial directions (e.g. in the slice selection direction, phase encoding direction or readout direction), these directions generally depending on the slice orientation selected. The logical spatial directions can likewise also coincide with the x-, y- and z-directions, e.g. slice selection direction in the z-direction, phase encoding direction in the y-direction, and readout direction in the x-direction. Magnetic resonance signals induced in the examination object O can be received via the body coil 5 which can also generally be used to emit the radiofrequency signals for inducing the magnetic resonance signals. However, these signals are usually received using a local coil arrangement 6 comprising local coils (of which only one is shown here) placed on or below the patient O, for example. All these components are known in principle to the person skilled in the art and are therefore only shown in an extremely schematic manner in FIG. 1.

The components of the magnetic resonance scanner 2 can be controlled by a control device 10. This can be a control computer which can also consist of a large number of individual computers—possibly also spatially separate and interconnected via suitable cables or the like. Said control device 10 is connected via a terminal interface 17 to a terminal 20 from which an operator can control the entire system 1. In this case the terminal 20 is equipped as a computer having a keyboard, one or more screens, and other input devices such as a mouse or the like, thereby providing the operator with a graphical user interface.

The control device 10 has, among other things, a gradient control unit 11 which can in turn consist of a plurality of sub-components. Control signals are applied to the individual gradient coils via said gradient control unit 11 according to a gradient pulse sequence GS. As described above, these are gradient pulses which are set (played out) at precisely predefined time positions and in a precisely predefined chronological sequence during a scan.

The control device 10 also has a radiofrequency transmit unit 12 for injecting RF pulses into the respective RF (body) coil 5 according to a predefined radiofrequency pulse sequence RFS of the pulse sequence. The radiofrequency pulse sequence RFS comprises, for example, excitation and refocusing pulses. The magnetic resonance signals ES are then received using the local coil arrangement 6, and the signal data ES received therefrom is read out by an RF receive unit 13.

Alternatively, a radiofrequency pulse sequence can also be emitted via the local coil arrangement, and/or the magnetic resonance signals can be received by the RF body coil (not shown) depending on how the RF body coil 5 and coil arrangements 6 are currently wired to the RF transmit unit 12 and RF receive unit 13 respectively. The use of the local coil arrangement is very important according to embodiments of the invention, as it is simpler in practice if the body resonator is not replaced, but a multi-core transmit/receive coil is added thereto.

Control commands are transmitted to other components of the magnetic resonance scanner 2, such as e.g. the couch 7 or main field magnet 3, or measured values and/or other information is received via another interface 18.

The gradient control unit 11, the RF transmit unit 12 and the RF receive unit 13 are each controlled in a coordinated manner by a scan control unit 15. By means of appropriate commands, this ensures that the desired gradient pulse sequences GS and radiofrequency pulse sequences RFS are emitted. It must also be ensured that the magnetic resonance signals are read out at the local coils of the local coil arrangement 6 by the RF receive unit 13 at the right time and further processed. The scan control unit 15 likewise controls the other interface 18. The scan control unit 15 can be constituted, for example, by a processor or a plurality of interacting processors.

The basic sequence of such a magnetic resonance scan and the control components mentioned are well known to the average person skilled in the art and will not therefore be discussed in further detail here. Moreover, a magnetic resonance scanner 2 of this kind and the associated control device can also comprise a plurality of other components which will likewise not be explained in detail here. It is pointed out at this juncture that the magnetic resonance scanner 2 can also be of different design, e.g. having a patient chamber open to the side, or implemented as a smaller scanner in which only one body part can be positioned.

In order to start a scan, a user can usually select, via the terminal 30, a control protocol P provided for said scan from a memory 16 in which a plurality of control protocols P for different scans are stored. Otherwise the user can also call up control protocols via a network NW, e.g. from a manufacturer of the magnetic resonance system, and then modify and use them as required.

The magnetic resonance system 1 according to an exemplary embodiment of the invention comprises an apparatus 30. The apparatus 30 for simultaneous imaging is indicated by dashed lines in FIG. 1 and comprises units distributed over the control device 10, as can be seen in FIG. 1. Part of the apparatus according to embodiments of the invention 30 is a transmit unit which comprises the gradient control unit 11 and the RF transmit unit 12. In addition, the apparatus 30 also incorporates the RF receive unit 13, a separation unit 21, a digitization unit 22, and a reconstruction unit 14. The operation of the units mentioned will now be described in detail. Multi-resonant RF excitation pulses α₁ comprising a plurality of sub-signals assigned to different types of atom are emitted by the RF transmit unit 12. In addition, a gradient scheme GS common to the different types of atom is transmitted by the gradient control unit 11. The RF transmit unit 12 additionally transmits the inversion pulses α₂ necessary for refocusing. In response, the atoms of different types excited by the RF excitation signals emit echo signals or more specifically magnetic resonance signals ES. The magnetic resonance signals ES received by the RF receive unit 13 are initially forwarded to the separation unit 21. The separation unit 21 receives the magnetic resonance signals ES received by the RF receive unit 13 and assigns them to the different types of atom involved in imaging. The separated individual signals EZS are then forwarded to the digitization unit 22. The digitization unit 22 converts the analog individual signals EZS into digitized raw data SRD of the separated individual signals. The digitized raw data SRD is then passed on to a reconstruction unit 14. The reconstruction unit 14 reconstructs the image data BD from the separated raw data SRD. The image data BD assigned to the atom types having the lower-value coupling constant γ is then further reduced to reduced image data RBD. Said image data BD which is outside a defined field of view FoV is discarded. The image data BD or RBD is stored in a memory 16 and/or transferred via the interface 17 to the terminal 20 so that the operator can view it. The image data BD or RBD can also be stored elsewhere and/or displayed and analyzed via a network NW. The image data BD, RBD comprises on the one hand the conventional image data reconstructed from the magnitude data of the separated raw data SRD and, on the other, also the phase images produced from the imaginary parts of the raw data during phase contrast measurement. The object being scanned can be visualized, separated by atom type, using the image data generated. However, the images produced can also be viewed superimposed on one another.

FIG. 2 shows by way of example a pulse sequence for simultaneous imaging using slice selection in the z-direction. In a first line marked RF, a multi-resonant excitation pulse α₁ and a multi-resonant inversion pulse α₂ are shown. These are followed chronologically by a spin echo ADC which is detected by a multi-resonant receive unit 13 (see FIG. 1). The gradient pulse sequences Gₓ, G_{y} and G_{z} are illustrated in lines 2 to 4. The purpose of the gradients Gₓ and G_{y} is to produce a spatial resolution in the x-direction and y-direction within the slice selected in the z-direction. For example, the gradient G_{y} can be a phase encoding gradient and a gradient Gₓ a readout gradient. In other words, during imaging, phase encoding is performed in the y-direction and frequency encoding is performed in the x-direction in the slice selected. A different phase is imposed in a location-dependent manner on the spins in the y-direction, and the frequency with which the spins process is varied in the x-direction. The signals read out therefore contain frequency and phase encoding defined by the gradient fields Gₓ and G_{y}, from which the image information can be reconstructed using a Fourier transform. However, the gradients affect the different types of atom differently, which means that the spins of the nuclei of the different types of atom are dephased at different speeds. The spatial resolution of the images obtained is dependent both on the gradient moments, i.e. the gradient field strength and the duration of action of the gradients, and on the coupling constant γ. Thus:

$$\frac{1}{Δ x} = \frac{γ}{2 π} \int {G}_{x} ( t ) d t \qquad ( 1 )$$

where Δx is the pixel edge length in the x-direction. For example, the lower value of the coupling constant γ of the Na²³ nucleus reduces the achievable resolution compared to H¹.

The number N of scan points required is obtained by dividing the size FoV of the object being scanned by the pixel size Δx achieved:

$$N = \frac{FOV}{Δ x} \qquad ( 2 )$$

Because of the lower value of the coupling constant of Na²³ compared to H¹, a lower resolution for Na²³ compared to H¹ is therefore produced for parallel scanning of the two atoms. Consequently, fewer scan points would suffice for Na²³ imaging. However, as scanning is designed according to embodiments of the invention to proceed simultaneously or at least using the same position encoding, more scan points than necessary are acquired for Na²³. As a result, a larger image region than necessary is acquired during excitation of the Na²³ atoms. For post processing of the image data, the pixels outside the defined FoV which corresponds to the size of the object being scanned or more precisely the size of the predetermined image region, are expediently discarded.

FIG. 3 shows a flow chart to illustrate a method according to an exemplary embodiment of the invention. In the exemplary embodiment shown, H¹ and Na²³ atoms are excited in a slice-selective imaging method using a spin echo pulse sequence. For this purpose, in step 3.I a dual-resonance excitation pulse α₁ is played out. This excitation pulse is emitted e.g. by a dual-resonance transmit antenna 12 (see FIG. 1) which transmits sub-signals assigned to different types of atom, the frequencies of which correspond to the resonant frequencies of the nuclear spins of said different atoms. The excitation pulse defines, together with the slice gradient G_{z}, the slice thickness of the target volume. The injected energy of the two sub-signals of the excitation signal α₁ generates under the effect of a simultaneously injected slice selection gradient G_{z} a different slice excitation for the individual types of atom. As already explained, this is due to the different values of the coupling constants γ_{NA23} and γ_{H1}. In order, for example, to obtain the same slice thickness for both types of atom, the ratio of the bandwidths BW_{Na} and BW_{H1} of the sub-signals of the excitation signal α₁ must be calculated as follows:

$$\frac{{BW}_{Na 23}}{{BW}_{H 1}} = \frac{{γ}_{Na 23}}{{γ}_{H 1}} . \qquad ( 3 )$$

In step 3.II, a multi-resonant RF inversion pulse α₂ is likewise transmitted simultaneously with a slice selection gradient G_{z}. The inversion pulse α₂ likewise comprises two sub-signals assigned to the different types of atom. In step 3.III, a gradient scheme GS common to the different types of atom or more specifically a gradient pulse sequence is transmitted. This is emitted e.g. via the transmit units 11 (see FIG. 1). Said gradient pulse sequence is synchronized with the emission of the excitation pulse α₁ and inversion pulse α₂. For example, the slice selection gradients G_{z}, as already described, are emitted simultaneously with the excitation pulse α₁ and the inversion pulse α₂. The readout gradient Gₓ, on the other hand, is synchronized with the readout window ADC of the receive device 13. The phase encoding gradients G_{y} are switched before and after readout. In step 3.IV, an echo signal or more precisely a magnetic resonance signal ES is received using a dual resonance receive antenna. The echo signal ES comprises different individual echos of different types of atoms. Then, in step 3.V, the received echo signal is separated into individual signals EZS. In step 3.VI, analog/digital conversion is performed prior to further processing. The separated individual signals or more precisely the corresponding separated digital raw data (SRD) are subsequently further processed separately. In the exemplary embodiment shown in FIG. 3, the pulse sequence is optimized for H¹ in respect of scan time, achievable SNR (signal-to-noise ratio) and resolution. In step 3.VII, the raw data SRD assigned to the H¹ individual signal can therefore be processed in the conventional manner in the same way as for image acquisition using H¹ atoms only. Image reconstruction comprises the usual mathematical methods such as e.g. Fourier transformation of the acquired raw data SRD. The raw data SRD assigned to the Na²³ individual signal is likewise used for reconstruction of the image data in step 3.VIII. However, in step 3.IX, the pixels lying outside the field of view FoV associated with image acquisition using the H¹ atoms are discarded, as these provide no additional information about the region of interest FoV.

An evaluation method is therefore provided which allows a pulse sequence developed per se only for MR imaging using one type of atom to be used for simultaneous scanning using a plurality of atom types. Consequently, additional information e.g. concerning the physiological and metabolic state of a patient can be obtained without having to spend additional scan time on a separate pulse sequence. In addition, interference effects occurring as the result of an object under examination moving during sequential scans are avoided.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements. The mention of a “unit” or a “module” does not preclude the use of more than one unit or module.

1. A simultaneous MR imaging method, comprising:
transmitting a multi-resonant RF excitation pulse comprising a plurality of sub-signals assigned to different types of atom;
transmitting a gradient scheme common to the different types of atom;
receiving an echo signal comprising different individual echoes of different types of atom;
separating the received echo signal into a plurality of individual signals; and
reconstructing image data on a basis of raw data assigned to the separated plurality of individual signals.

2. The method as claimed in claim 1, wherein a multi-resonant RF inversion pulse is transmitted comprising a plurality of sub-signals assigned to different types of atom, and/or an inverted gradient pulse is transmitted so that the spins of the excited atoms are refocused.

3. The method as claimed in claim 1, wherein the echo signals of just two types of atom are simultaneously measured.

4. The method as claimed in claim 1, wherein the different types of atom comprise one of the following types of atom:
H¹,
Na²³,
F¹⁹,
P³¹,
C¹⁴,
He³,
Li⁷,
Cl³⁵,
Cl³⁷.

5. The method as claimed in claim 1, wherein the gradient scheme is optimized in respect of the resonance or image resolution of hydrogen atoms.

6. The method as claimed in claim 1, wherein the RF excitation pulse and the RF inversion pulse are emitted in a slice-selective manner.

7. The method as claimed in claim 1, wherein the ratios of the bandwidths of the plurality of sub-signals of the multi-resonant RF excitation pulse correspond to the ratios of the values of the gyromagnetic factors of the different types of atom.

8. The method as claimed in claim 1, wherein the ratios of the bandwidths of the plurality of sub-signals of the multi-resonant RF inversion pulse correspond to the ratios of the values of the gyromagnetic factors of the different types of atom.

9. The method as claimed in claim 1, wherein a 3D sequence is used as the gradient scheme.

10. The method as claimed in claim 1, wherein separated image data is obtained from the separated individual signals of the different types of atom and the pixels of the image data lying outside the region of interest are not taken into account.

11. The method as claimed in claim 1, wherein k-space is sampled line by line and/or radially during readout of the echo signals.

12. The method as claimed in claim 1, wherein the RF pulses for different types of atom are transmitted sequentially instead of simultaneously, but during the same common gradient pulse.

13. An apparatus for simultaneous imaging, comprising:
a transmit unit which is designed:
to transmit a multi-resonant RF excitation pulse comprising a plurality of sub-signals assigned to different types of atom,
and
to transmit a gradient scheme common to the different types of atom;
a receive unit which is designed to receive an echo signal comprising different individual echoes of different types of atom;
a separation unit which is designed to separate the echo signal into a plurality of individual signals; and
a reconstruction unit which is designed to reconstruct image data on a basis of raw data assigned to the separated plurality of individual signals.

14. A magnetic resonance system having an apparatus as claimed in claim 13.

15. A computer program product which is loaded directly into a memory of the magnetic resonance system and having program code sections for carrying out all the steps of the method as claimed in claim 1.
